(19) United States
(12) Patent Application Publication
(10) Pub. No.: US 2013/0298836 A1
(43) Pub. Date: Nov. 14, 2013

(54) VAPOR PHASE GROWTH APPARATUS

(71) Applicants: Kazutada Ikenaga, Tokyo (JP); Kosuke Uchiyama, Tokyo (JP)

(72) Inventors: Kazutada Ikenaga, Tokyo (JP); Kosuke Uchiyama, Tokyo (JP)

(73) Assignees: TN EMC LTD., Tama-city (JP); TAIYO NIPPON SANSO CORPORATION, Tokyo (JP)

(21) Appl. No.: 13/821,426

(22) PCT Filed: Jan. 18, 2012
(86) PCT No.: PCT/JP12/50892

§ 371 Date: Mar. 7, 2013

(30) Foreign Application Priority Data
Feb. 3, 2011 (JP) 2011-021505

(51) Int. Cl. C23C 14/50

(52) U.S. Cl. CPC C23C 14/505
USPC 118/730

(57) ABSTRACT

Provided is a vapor phase growth apparatus having a rotation/revolution mechanism by which a rolling member is prevented from riding onto an adjacent rolling member. In a vapor phase growth apparatus having a rotation/revolution structure in which a plurality of substrate retaining members 21 are rotatably provided in the circumferential direction of the susceptor via a rolling member(ball 22,23) on a susceptor 11, heated by a heating unit as well as is rotated by a driving unit, the substrate retaining member is rotated accompanied by the rotation of the susceptor and a substrate 12 retained by the substrate retaining member is rotated while being revolved with respect to the rotation axis of the susceptor. As for the rolling members, rolling members different diameters (a large diameter ball 22 and a small diameter ball 23) are alternately arranged.

### TECHNICAL FIELD

The present invention relates to a vapor phase growth apparatus, and particularly, to a vapor phase growth apparatus having a mechanism in which a substrate on a susceptor is rotating/revolving.

### BACKGROUND ART

As a vapor phase growth apparatus in which, in a state in which a substrate retained on a susceptor in a flow channel is heated to a predetermined temperature, a gas phase material is supplied in the flow channel to deposit a thin film on the surface of the substrate, known is a vapor phase growth apparatus having, in order to form a thin film uniformly on a plurality of substrates, a mechanism in which a susceptor is rotated while a substrate retaining member (substrate tray) which retains a substrate is rotated accompanied by the rotation of the susceptor, that is, the substrates during deposition are rotating/revolving (see, for example, Patent Document 1). In such a rotation/revolution mechanism, a rolling member (bearing) is laid between the susceptor and the substrate retaining member, which allows the substrate retaining member to rotate smoothly (see, for example, Patent Document 1).

### PRIOR ART REFERENCE

### Patent Document

Patent Document 1: JP-A 2007-243060

### SUMMARY OF THE INVENTION

### Problems to be Solved by the Invention

In a rotation/revolution mechanism of a conventional vapor phase growth apparatus, since adjacent rolling members rotate in opposite directions, the back rolling member in the rotation direction may run onto the front rolling member in the rotation direction when the surface of the rolling member deteriorates and the frictional force increases. For this reason, the rolling members need to be replaced with new ones periodically. In order to replace the rolling members, the whole susceptor needs to be taken out of the chamber, which is time-consuming and costly, since large-scale maintenance, such as a release of the chamber, becomes necessary.

Accordingly, an object of the present invention is to provide a vapor phase growth apparatus having a rotation/revolution mechanism by which a rolling member is prevented from riding onto an adjacent rolling member.

### Means for Solving the Problem

In order to attain the above-mentioned object, the vapor phase growth apparatus of the present invention is a vapor phase growth apparatus having a rotation/revolution structure in which a plurality of substrate retaining members are rotatably provided in the circumferential direction of the susceptor via a rolling member on a susceptor which is heated by a heating unit as well as is rotated by a driving unit, the substrate retaining member is rotated accompanied by the rotation of the susceptor and a substrate retained by the substrate retaining member is rotated while being revolved with respect to the rotation axis of the susceptor, characterized in that, for the rolling members, rolling members having different diameters are alternately arranged.

### Advantages of the Invention

In the vapor phase growth apparatus of the present invention, by alternately arranging rolling members having different diameters, the adjacent rolling members can rotate in the same direction. A rolling member can therefore be prevented from being ridden onto another rolling member, which can sustain a stable rotating state over a long period of time.

### BRIEF DESCRIPTION OF THE DRAWINGS

FIG. 1 is a cross-sectional view of one embodiment of a vapor phase growth apparatus of the present invention.

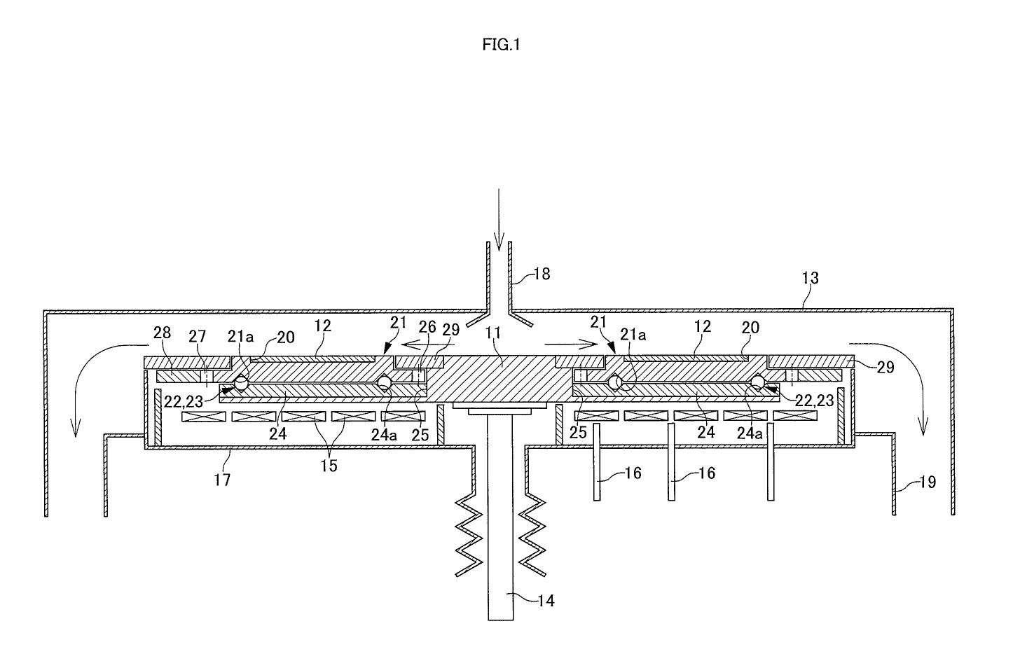

FIG. 2 is a plan view of a susceptor.

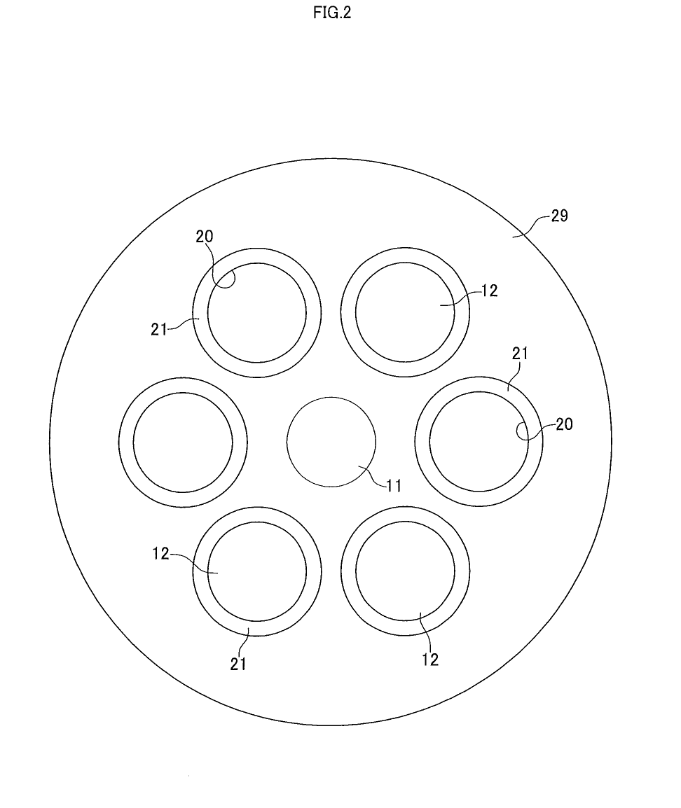

FIG. 3 is an illustrative view of a main part.

### MODES FOR CARRYING OUT THE INVENTION

The vapor phase growth apparatus illustrated in the present embodiment is a multiple rotation/revolution type vapor phase growth apparatus in which six substrates 12 can be mounted on the upper surface of a disk-shaped susceptor 11, wherein the susceptor 11 is rotatably placed inside a cylindrical flow channel 13 which is formed of quartz glass or the like. A rotation axis 14 is provided at a center portion of the lower surface of the susceptor 11, and a heater 15 or a thermometer 16 for heating the substrate 12 is individually provided around the rotation axis 14 via the susceptor 11. A lower part of and the circumference of the heater 15 are covered with a reflector 17. A gas phase material inlet 18 is provided at a center of the top plate of the flow channel 13 as an opening, and an exhaust port 19 is provided at the outer circumference of a bottom plate.

The substrate 12 is retained by a disk-shaped substrate retaining member (substrate tray) 21 having a substrate retaining concave portion 20 on the upper surface. The substrate retaining member 21 is supported by each disk-shaped guide member 24 via rolling members formed of carbon or ceramics and having different diameters which are two types of balls 22, 23 having a large diameter and a small diameter respectively. The guide members 24 are retained in a guide member retaining concave portion 25 provided at regular intervals in the circumferential direction of the susceptor 11. An external gear 26 is provided at the bottom of the outer circumference of the substrate retaining member 21, and a ring-shaped fixed gear member 28 having an internal gear 27 which meshes with an external gear 26 of the substrate retaining member 21 is provided at a position on the outer circumference of the susceptor 11. Further, a cover member 29 covering an upper portion of the fixed gear member 28, upper portions of the internal gear 27 and the external gear 26, and the upper surface of a center portion of the susceptor 11 is provided. The upper surface of the cover member 29, the upper surface of the outer circumference portion of the substrate retaining concave portion 20, and the upper surface of the substrate 12 are flushed with each other.

Ring-shaped V-grooves 21a and 24a around the axis of the substrate 12 are provided facing each other respectively on the lower surface of each substrate retaining member 21 and the upper surface of each guide member 24, which are facing each other. Between both of the V-grooves 21a and 24a, the balls 22 and 23 are rotatably retained. Since the guide member 24 is formed separately from the susceptor 11 due to manufacturing reasons, it is also possible to form an equivalent guide member 24 provided with a V-groove 24a integrally on the susceptor 11.

In the case where vapor phase growth is performed on the substrate 12, when the rotation axis 14 is rotated at a predetermined velocity, the susceptor 11 is rotated together with the rotation axis 14 and every member except a fixed gear member 28 is rotated accompanied by the rotation of the susceptor 11; the substrate 12 rotates around the axis of the susceptor 11, that is, the substrate 12 revolves. In addition, since an internal gear 27 of the fixed gear member 28 is meshed with an external gear 26, the substrate retaining member 21 rotates around the axis of the substrate retaining member 21, that is, the substrate retaining member 21 revolves. By this, the substrate 12 retained by the substrate retaining member 21 rotates/revolves around the axis of the susceptor 11.

As mentioned above, in a state in which the substrate 12 is rotated/revolved, and the substrate 12 is heated at a predetermined temperature, for example 1100° C. with a heater 15 via the susceptor 11 or the like, by introducing predetermined gas phase materials such as trimethylgallium and ammonia from a gas phase material inlet 18 into the flow channel 13, a predetermined thin film can be uniformly deposited on the surfaces of a plurality of the substrates 12.

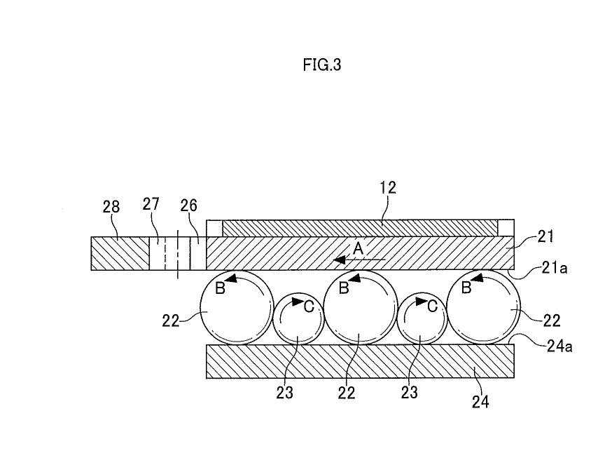

As mentioned above, in the case where a thin film is deposited on the surface of the substrate 12, since, among two types of small and large balls 22, 23 arranged between the V-groove 21a on the substrate retaining member 21 and the V-groove 24a on the guide member 24, the ball having a large diameter (large diameter ball) 22 is sandwiched between V-grooves 21a and 24a on the top and the bottom and is in contact with both of the V-grooves, when the substrate retaining member 21 rotates in the direction of the arrow A in FIG. 3 with respect to the revolving guide member 24, the large diameter ball 22 rotates in the rotation direction of the substrate retaining member 21 represented by the arrow B in FIG. 3. On the other hand, since the distance between the V-grooves 21a and 24a is determined by the diameter of the large diameter ball 22, the ball having a smaller diameter (small diameter ball) 23 compared to the large diameter ball 22 is in a state of being in contact only with the V-groove 21a of the substrate retaining member 21 positioned below due to its own weight. The small diameter ball 23 is thus pushed by the large diameter ball 22 which rotates in the direction (arrow B) to the rotation direction (arrow A) of the substrate diameter ball 23, and the small diameter ball 23 proceeds in the V-groove 21a of the substrate retaining member 21 to the rotation direction of the substrate retaining member 21.

Since the surfaces of both the V-grooves 21a and 24a and the surfaces of the both balls 22 and 23 are finished in a sufficiently smooth state at the time of manufacturing, the frictional force between the small diameter ball 23 and the large diameter ball 22 is sufficiently small, and in whichever direction the small diameter ball 23 revolves with respect to the large diameter ball 22, the large diameter ball 22 does not ride onto the small diameter ball 23, whereby the substrate retaining member 21 rotates in a stable state.

When the surfaces of the both balls 22 and 23 deteriorate due to changes over time, and the frictional force between the small diameter ball 23 and the large diameter ball 22 becomes larger than the frictional force between the small diameter ball 23 and the V-groove 21a, the small diameter ball 23 will be pushed by the large diameter ball 22 and will slide within the V-groove 21a, becoming in a state in which the small diameter ball 23 rotates in the direction of the arrow C opposite to the rotation direction (arrow B) of the large diameter ball 22. Accordingly, since a contact portion of the neighboring balls 22 and 23 becomes in a state in which the contact portion rotates in such a manner that the contact portion proceeds in the same direction, the large diameter ball 22 does not drive onto the small diameter ball 23 and the substrate retaining member 21 rotates in a stable state supported by the large diameter ball 22.

Accordingly, by alternately arranging two types of large and small balls 22 and 23 having different diameters between the V-groove 21a of the substrate retaining member 21 and the V-groove 24a of the guide member 24, even when the surfaces of both the balls 22 and 23 deteriorate and the frictional force increases, a ball will not ride onto the other ball and the substrate retaining member 21, that is, the substrate 12 can be rotated in a stable state for a long period of time.

The diameter of the small diameter ball 23 may be set such that the small diameter ball 23 is not in contact with the surface of the V-groove 21a of the substrate retaining member 21 supported by the large diameter ball 22 and such that the ball 23 is sandwiched between large diameter balls 22, and usually may be set to a diameter 0.1 to 10% smaller than the diameter of the large diameter ball 22. Note that when the difference between the diameters thereof is too small, it becomes difficult to confirm that the balls 22 and 23 are alternately arranged; when the difference between the diameters thereof is too large, the number of the balls increases, which is uneconomical, and the rotational resistance of the ball having a small diameter increases as well. At the time of manufacturing, the frictional force between both of the balls 22 and 23 can also be made larger than the frictional force between the small diameter ball 23 and the V-groove 21a. Further, the large diameter ball 22 and the small diameter ball 23 can be formed of different materials.

The present invention can also be applied to a vapor phase growth apparatus in which the thin film forming surface of the substrate is facing downward, and can also be used for a revolving type vapor phase growth apparatus in which a substrate is revolved with respect to the rotation axis of a susceptor and a rotating type vapor phase growth apparatus in which only rotation is performed. Further, the shape of each portion can be appropriately set depending on variety of conditions such as the size of a susceptor or a substrate. A cover member can be omitted and the shape of the rolling member is not limited to a ball and the retaining of the rolling member is not limited to a V-groove.

### Description of Symbols

susceptor, 12 . . . substrate, 13 . . . flow channel, 14 . . . rotation axis, 15 . . . heater, 16 . . . thermometer, 17 . . . reflector, 18 . . . gas phase material inlet, 19 . . . exhaust port, 20 . . . substrate retaining concave portion, 21 . . . substrate retaining member, 21a . . . V-groove, 22 . . . large diameter ball, 23 . . . small diameter ball, 24 . . . guide member, 24a . . . V-groove, 25 . . . guide member retaining concave portion, 26 . . . external gear, 27 . . . internal gear, 28 . . . fixed gear member, 29 . . . cover member

1. A vapor phase growth apparatus having a rotation/revolution structure in which a plurality of substrate retaining members are rotatably provided in the circumferential direction of the susceptor via a rolling member on a susceptor which is heated by a heating unit as well as is rotated by a driving unit, the substrate retaining member is rotated accompanied by the rotation of the susceptor and a substrate retained by the substrate retaining member is rotated while being revolved with respect to the rotation axis of the susceptor, characterized in that, for the rolling members, rolling members having different diameters are alternately arranged.
